(19) United States
(12) Patent Application Publication
(10) Pub. No.: US 2010/0096611 A1
(43) Pub. Date: Apr. 22, 2010

(54) VERTICALLY INTEGRATED MEMORY STRUCTURES

(75) Inventors: Xuguang Wang, Eden Prairie, MN (US); Yiran Chen, Eden Prairie, MN (US); Dimitar V. Dimitrov, Edina, MN (US); Hongyue Liu, Maple Grove, MN (US)

Correspondence Address: CAMPBELL NELSON WHIPPS, LLC, HISTORIC HAMM BUILDING, 408 SAINT PETER STREET, SUITE 240, ST. PAUL, MN, 55102, US

(73) Assignee: SEAGATE TECHNOLOGY LLC, Scotts Valley, CA (US)

(21) Appl. No.: 12/252,645

(22) Filed: Oct. 16, 2008

(51) Int. Cl. H01L 45/00; H01L 27/115; H01L 21/336

(52) U.S. Cl. 257/4; 257/252; 438/3; 438/102; 257/E27.103; 257/E45.002; 257/E21.409

(57) ABSTRACT

A device including a transistor that includes a source region; a drain region; and a channel region, wherein the channel region electrically connects the source region and the drain region along a channel axis; and a memory cell, wherein the memory cell is disposed adjacent the drain region so that the channel axis runs through the memory cell.

### BACKGROUND

New types of memory have demonstrated significant potential to compete with commonly utilized types of memory. For example, non-volatile spin-transfer torque random access memory (referred to herein as “STRAM”) has been discussed as a “universal” memory. The ability of STRAM to more effectively compete with established memory types, such as FLASH memory (NAND or NOR) can be maximized by either decreasing the current density or increasing the density at which STRAM cells can be formed on a chip.

A memory structure 100, depicted by FIG. 1a, utilizes a transistor 110 and a memory cell 130 that are formed separately and are utilized together. A commonly utilized transistor is a metal-oxide-semiconductor field-effect transistor (a “MOSFET”). As seen in FIG. 1a, a transistor 110 generally includes a source 112 and a drain 114 formed within or on a substrate 116. Once a voltage larger than the threshold voltage is applied to the gate 120, electrons will flow from the source 112 (and possibly the drain 114) through the channel region 118. The length of the channel region L dictates at least in part how easy it is to control the transistor (i.e. prevent leakage across the channel region).

The transistor 110 is electrically connected to a memory cell 130. Connection 150 illustrates the operative connection between the transistor 110 and the memory cell 130. The illustrative memory cell in FIG. 1a includes a first magnetic layer 132, an insulating layer 134 and a second magnetic layer 136. The nominal dimension of the memory cell 130 in this illustrative example is given as F.

FIG. 1b illustrates a top view and the relevant dimensions of the device depicted in FIG. 1a. FIG. 1b shows the area required by a single memory cell (designated as existing in the dashed area 131). It is assumed for this calculation that the area 131 has an approximate width of F and a length of 2 F. As seen from FIG. 1b, the single memory cell, when constructed as seen in FIG. 1a, generally requires an area of (x) (y). The dimension x is given by the length of the gate (L) plus the length of the drain 114 (D). The source 112 of one cell generally functions as the drain of the next cell, and therefore the length of the source is not relevant to the dimension x. Utilizing the approximate dimensions of the area 131, L+D is about 2.5 F. The dimension y is given by the width of the channel (W) plus the space that is necessary between cells (Space). The area of each unit cell as depicted in FIG. 1a is then (2.5 F) (W+Space).

### BRIEF SUMMARY

A device including a transistor that includes a source region; a drain region; and a channel region, wherein the channel region electrically connects the source region and the drain region along a channel axis; and a memory cell, wherein the memory cell is disposed above the drain region so that the channel axis runs through the memory cell.

These and various other features and advantages will be apparent from a reading of the following detailed description.

### BRIEF DESCRIPTION OF THE DRAWINGS

The disclosure may be more completely understood in consideration of the following detailed description of various embodiments of the disclosure in connection with the accompanying drawings, in which:

FIGS. 1a and 1b are a plan view (FIG. 1a) and a top view (FIG. 1b) of memory cells;

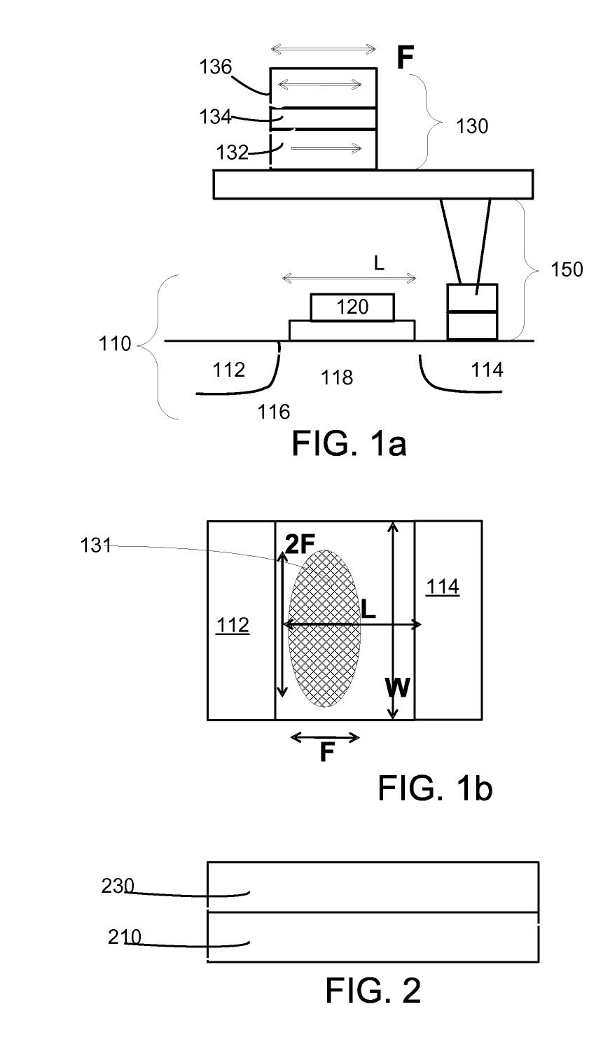

FIG. 2 is an illustration of a device as disclosed herein;

FIG. 3a and 3b are plan views (FIG. 3a) and a plan perspective view (FIG. 3b) of devices as disclosed herein;

FIG. 4 is a plan view of an embodiment of a device as disclosed herein;

FIGS. 5a, 5b and 5c are a plan perspective view (FIG. 5a) and cross section views along the z-x plane (FIG. 5b) and the x-y plane (FIG. 5c) of an embodiment of a device as disclosed herein; FIG. 5d is a plan perspective view of an embodiment of a device as disclosed herein that includes three memory cells;

FIGS. 6a and 6b are illustrations of STRAM memory cells that can be utilized in embodiments of devices as disclosed herein;

FIG. 7 is an illustration of a RRAM cell that can be utilized in embodiments of devices as disclosed herein;

FIG. 8a through 8k depict an exemplary method of forming a device as disclosed herein; and

FIGS. 9a and 9b are illustrations of embodiments of devices as disclosed herein.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

In the following description, reference is made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

The present disclosure provides advantageous memory devices and methods of manufacturing the memory devices. The memory devices generally offer advantages because of the relatively smaller areas that are required for individual memory cells.

Disclosed herein is a device that includes a transistor and a memory cell. Generally, within a memory device, a transistor is powered to supply current to a memory cell. The data contained within the memory cell can then be determined based on the resistance of the cell. For example, in a STRAM cell, the resistance will be low if the free layer of the cell is aligned parallel with the pinned layer and high if the free layer of the cell is aligned anti-parallel to the pinned layer. Each memory cell therefore is operatively coupled to a transistor. As used herein, “operatively coupled” is defined as leaning the components are electrically interconnected either directly or indirectly through other elements, devices or components so as to provide functionality for a given operation, e.g., reading or writing data from the memory cell.

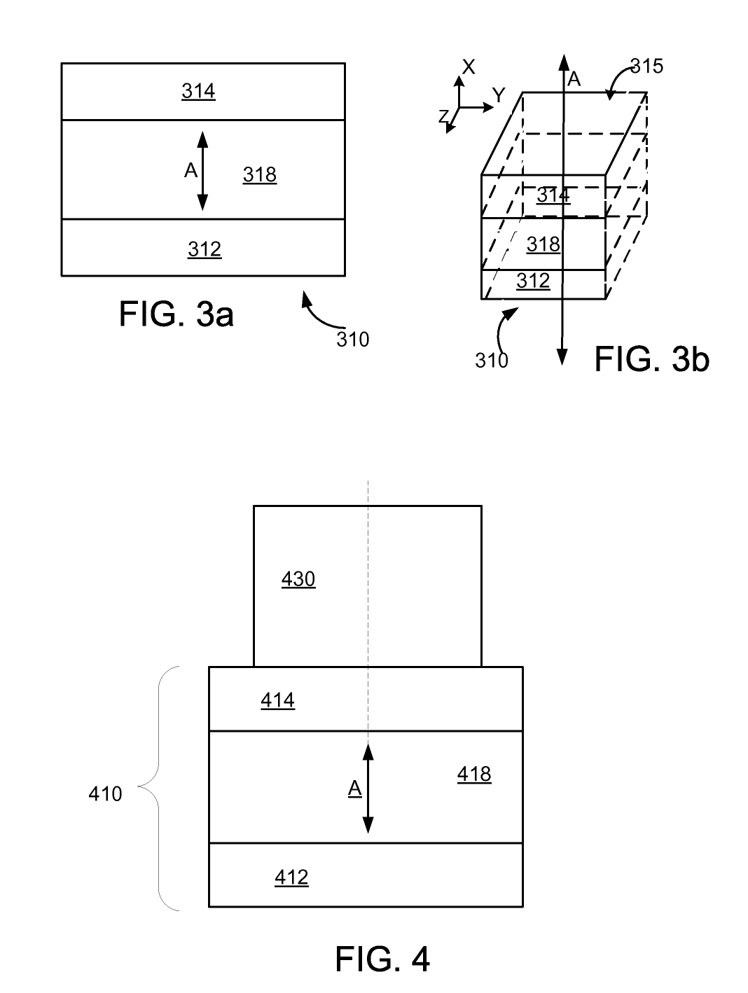

A device as disclosed herein includes a transistor and a memory cell. An exemplary device as disclosed herein is depicted in FIG. 2. A device as disclosed herein includes a transistor 210 and a memory cell 230. In an embodiment, the transistor 210 can, but need not be a metal-oxide-semiconductor field effect transistor (“MOSFET”). The memory cell 230 is disposed on a surface of the transistor 210. Generally, the transistor 210 and the memory cell 230 can be said to have a vertical alignment, i.e. the memory cell 230 is disposed vertically on top of the transistor 210.

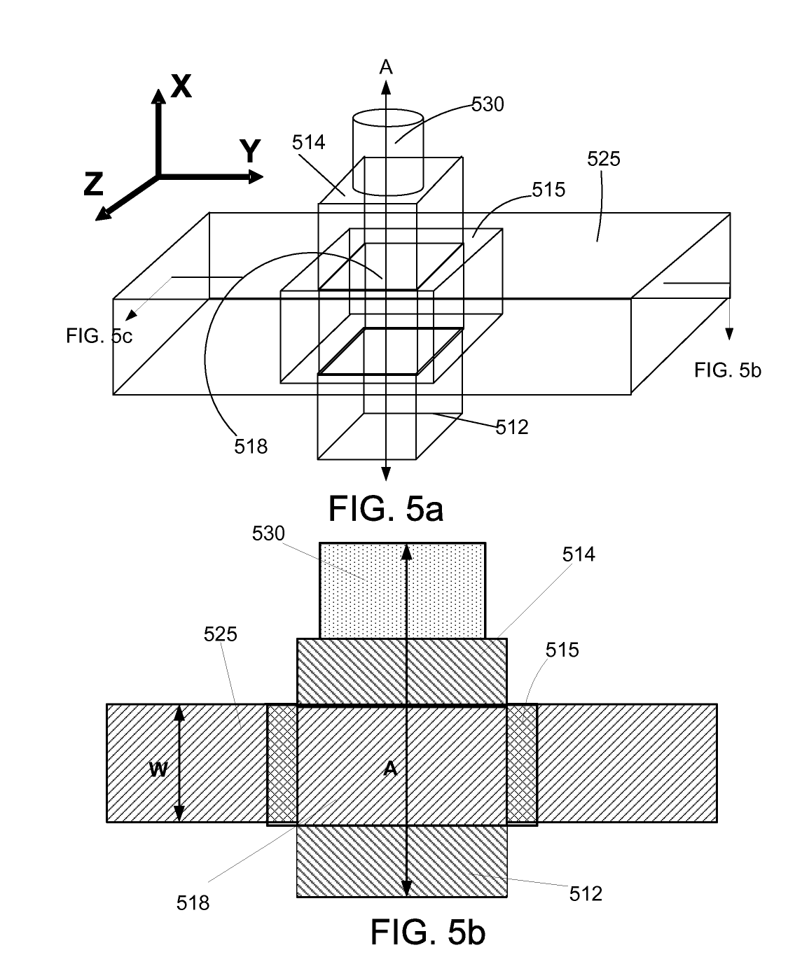

A location of a memory cell can be further described based on the transistor. A transistor that can be utilized in a device as disclosed herein includes a source region, a drain region and a channel region. FIG. 3a illustrates an exemplary configuration of these components. In a transistor as utilized herein, and as seen in FIG. 3a, the source region 312 and the drain region 314 are separated by a channel region 318. In an embodiment, the source region 312 and the drain region 314 are opposed on opposite sides of the channel region 318. Generally, the channel region 318 electrically connects the source region 312 and the drain region 314 along a channel axis, which is illustrated by the arrow A. The channel axis is generally the axis of the channel region 318. In an embodiment, the channel axis can also be defined by the direction of bulk flow of electrons from the source region 312 to the drain region 314 or vice versa.

FIG. 3b illustrates another method of describing the configuration of the transistor and its location relative to the memory cell. The transistor 310 in FIG. 3b includes a source region 312, a channel region 318 and a drain region 314. These components are disposed along the X axis (as given by the Cartesian coordinates in FIG. 3b). The X axis in this illustration is generally parallel to the channel axis A, as designated by the arrow A in FIG. 3b. In this illustration, the memory cell would be disposed on the first surface 315 of the transistor 310.

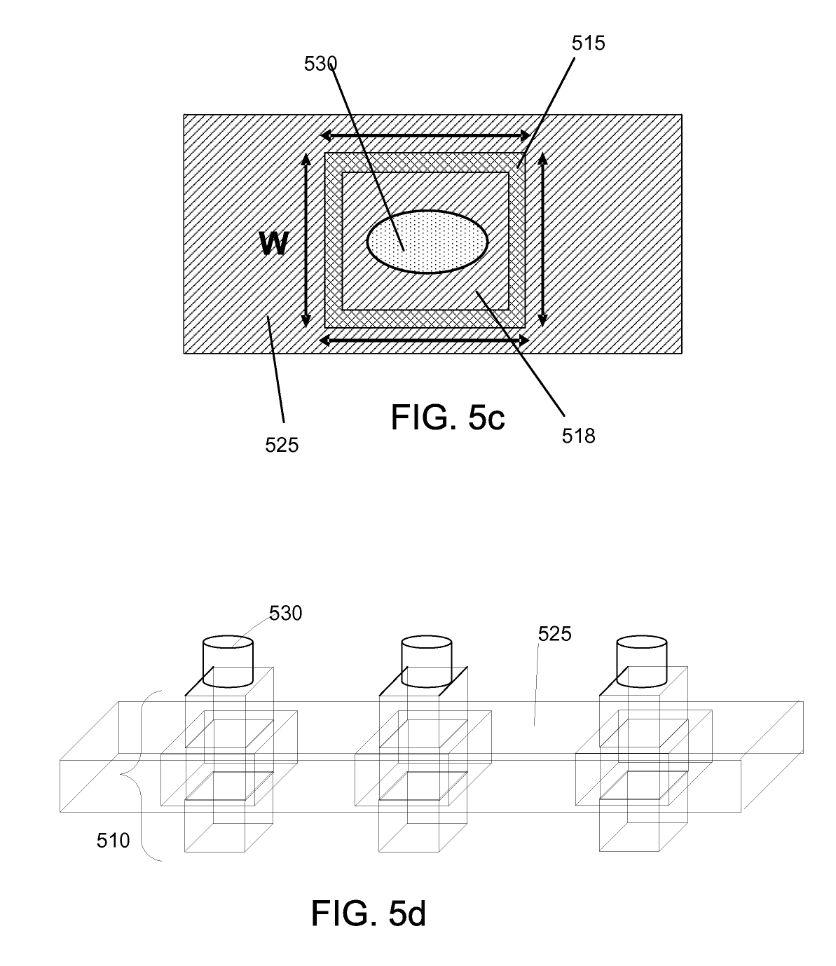

FIG. 4 illustrates a memory cell 430 disposed on a transistor 410. In an embodiment, the memory cell 430 can be adjacent to, on, or directly on the transistor 410. As seen in FIG. 4, the memory cell 430 is positioned upon the transistor 410 in such a way that the channel axis, A runs through the memory cell 430 (as shown by the dotted line extending through the memory cell 430). It should be noted that although depicted as such, the channel axis A need not be the axis of the memory cell 430 as well. The memory cell 430 can be placed on the transistor in such a way that the channel axis is not the same as the axis of the memory cell 430, for example, the memory cell could be positioned on the transistor 410 so that the channel axis is only parallel to the axis of the memory cell.

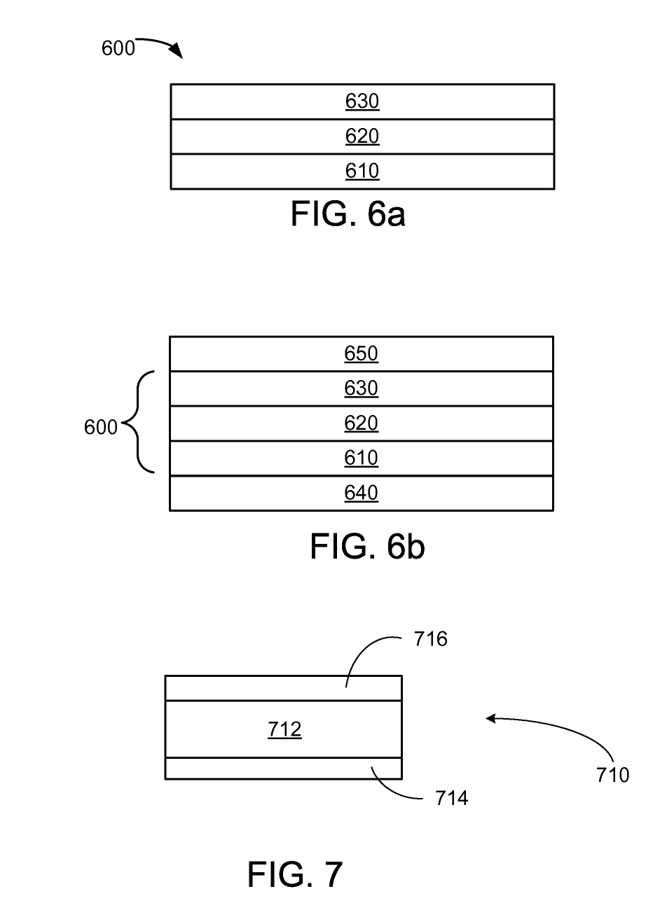

FIG. 5a depicts a three-dimensional view of a memory device as described herein. As seen there, the memory cell 530 is disposed on the drain region 514. The drain region 514 is in turn disposed on the channel region 518, which is disposed on the source region 512. FIG. 5a depicts the channel axis A along the entire vertical length of the device. As seen there, the memory cell 530 is disposed on the drain region so that the channel axis runs through the memory cell 530. The gate oxide region 515 surrounds the channel region 518. The channel region 518 and the gate oxide region 515 are generally disposed in a word line 525. FIG. 5b depicts a cross section of the same memory device, cut along the z-x plane (as shown by the arrow on the right of FIG. 5a). The structures that are shown in FIG. 5b are numbered the same as FIG. 5a and FIG. 5b. As noted in FIG. 5b, the length of the channel region 518 (the distance from the source region 512 to the drain region 514) is related to the thickness of the word line 525, which is designated by W. FIG. 5c depicts a cross section of the same memory device, cut along the y-x plane (as shown by the arrow on the left of FIG. 5a). The structures that are shown in FIG. 5c are numbered the same as FIG. 5a. It should be noted in FIG. 5c that the channel region 518 is seen surrounding the memory cell 530; depending on the location (in the z direction) where the cross section was taken, the channel region 518 could be replaced by either the drain region 514 (going vertically up the device) or by the source region 512 (going vertically down the device). This view of the device also exemplifies that the effective channel width of the channel region 518 is actually 4 W because the channel region is encompassed on four sides by the word line 525. Therefore, the driving current can be increased four times (4×) while using a much smaller area of the silicon substrate. FIG. 5d illustrates how more than one memory device (transistor 510 and memory cell 530) can be disposed along a single word line 525.

A memory cell utilized in a memory device as described herein can include many different types of memory. Exemplary types of memory that can be utilized in devices disclosed herein include, but are not limited to, ferroelectric RAM (FeRAM or FRAM); magnetoresistive RAM (MRAM); resistive RAM (RRAM); phase change memory (PCM) which is also referred to as PRAM, PCRAM and C-RAM; programmable metallization cell (PMC) which is also referred to as conductive-bridging RAM or CBRAM; and spin torque transfer RAM, which is also referred to as STRAM.

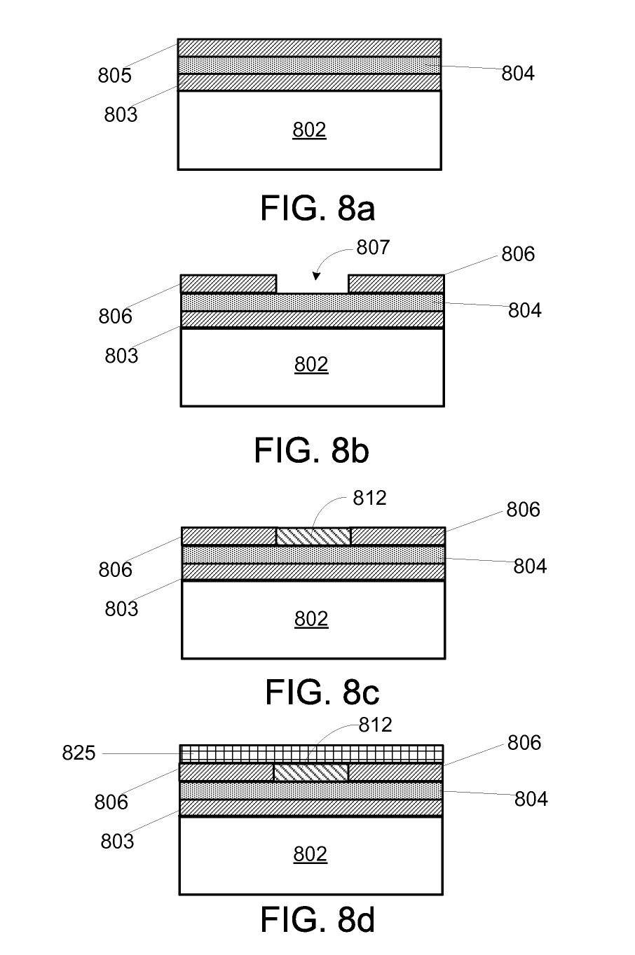

In an embodiment, the memory cell can be STRAM. STRAM memory cells include a MTJ (magnetic tunnel junction), which generally includes two magnetic electrode layers separated by a thin insulating layer known as a tunnel barrier. An embodiment of a MTJ is depicted in FIG. 6a. The MTJ 600 in FIG. 6a includes a first magnetic layer 610 and a second magnetic layer 630, which are separated by an insulating layer 620. FIG. 6b depicts a MTJ 600 in contact with a first electrode layer 640 and a second electrode layer 650. The first electrode layer 640 and the second electrode layer 650 electrically connect the first magnetic layer 610 and the second magnetic layer 630 respectively to a control circuit (not shown) providing read and write currents through the magnetic layers. The relative orientation of the magnetization vectors of the first magnetic layer 610 and the second magnetic layer 630 can be determined by the resistance across the MTJ 600.

The first magnetic layer 610 and the second magnetic layer 630 are generally made of ferromagnetic alloys such as iron (Fe), cobalt (Co), and nickel (Ni) alloys. In an embodiment, the first magnetic layer 610 and the second magnetic layer 630 can be made of alloys such as FeNm, NiO, IrMn, PtPdMn, NiMn and TbCo for example. The insulating layer 620 is generally made of an insulating material such as aluminum oxide (Al₂O₃) or magnesium oxide (MgO).

The magnetization of one of the magnetic layers, for example the first magnetic layer 610 is generally pinned in a predetermined direction, while the magnetization direction of the other magnetic layer, for example the second magnetic layer 630 is free to rotate under the influence of a spin torque. Pinning of the first magnetic layer 610 may be achieved through, e.g., the use of exchange bias with an antiferromagnetically ordered material such as PtMn, IrMn and others.

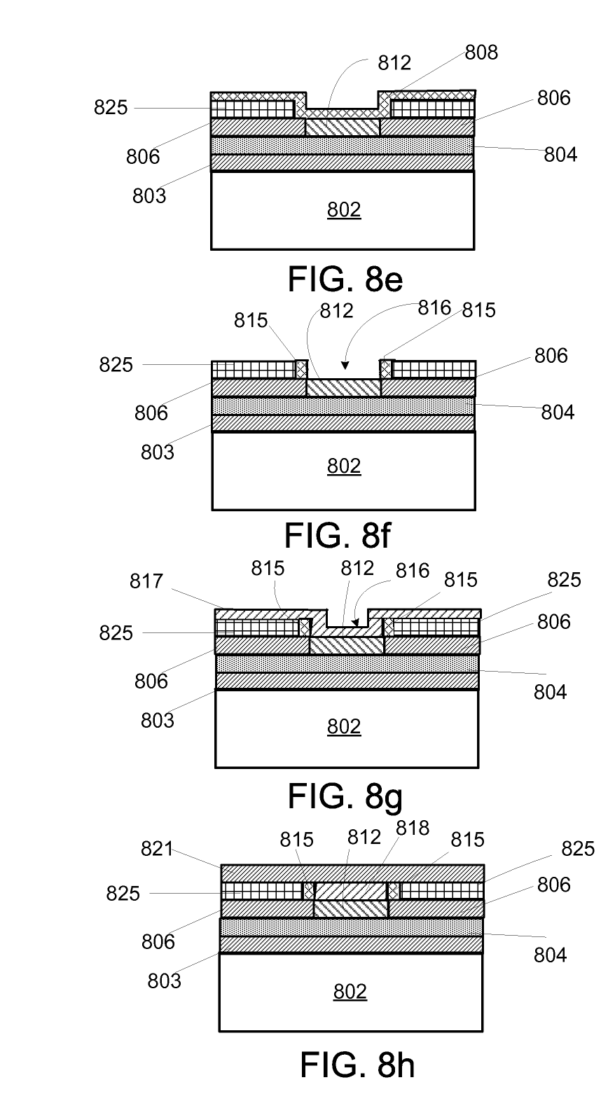

In an embodiment, the memory cell can be RRAM. FIG. 7 is a schematic diagram of an illustrative resistive random access memory (RRAM) cell 710. The RRAM cell 710 includes a medium layer 712 that responds to an electrical current or voltage pulse by altering an electrical resistance of the medium layer 712. This phenomenon can be referred to as the electrical pulse induced resistance change effect. This effect changes the resistance (i.e., data state) of the memory from a one or more high resistance state(s) to a low resistance state, for example. The medium layer 712 is interposed between a first electrode 714 and a second electrode 716 and acts as a data storage material layer of the RRAM cell. The first electrode 714 and a second electrode 716 are electrically connected to a voltage source (not shown). The first electrode 714 and a second electrode 716 can be formed of any useful electrically conducting material such as, for example, a metal.

The material forming the medium layer 712 can be any known useful RRAM material. In some embodiments, the material forming the medium layer 712 includes an oxide material such as, for example, a metal oxide. In some embodiments, the metal oxide is a binary oxide material or complex metal oxide material. In other embodiments, the material forming the medium layer 712 includes a chalcogenide solid electrolyte material or an organic/polymer material.

The binary metal oxide material can be expressed as a chemical formula of MₓO_{y}. In this formula, the characters “M”, “O”, “x”, and “y” refer to metal, oxygen, a metal composition ratio, and an oxygen composition ratio, respectively. The metal “M” may be a transition metal and/or aluminum (Al). In this case, the transition metal may be nickel (Ni), niobium (Nb), titanium (Ti), zirconium (Zr), hafnium (Hf), cobalt (Co), iron (Fe), copper (Cu) and/or chrome (Cr). Specific examples of binary metal oxides that may be used as the medium layer 12 include CuO, NiO, CoO, ZnO, CrO₂, TiO₂, HfO₂, ZrO₂, Fe₂O₃, and Nb₂O₅.

In some embodiments, the metal oxide can be any useful complex metal oxide such as, for example, a complex oxide material having a formula Pr_{0.7}Ca_{0.3}MnO₃, or SrTiO₃, or SiZrO₃, or these oxides doped with Cr or Nb. The complex can also include LaCuO₄, or Bi₂Sr₂CaCu₂O₈. One example of a solid chalcogenide material is a germanium-selenide (GeₓSel₁₀₀₋ₓ) containing a silver (Ag) component. One example of an organic material is Poly(3,4-ethylenedioxythiophene) (i.e., PEDOT).

The memory cell can also include ferroelectric capacitors having structures similar to FIG. 7 using materials such as lead zirconate titanate (referred to as “PZT”) or SrBi₂Ta₂O₉ (referred to as “SBT”). In such memory cells, an electrical current can be used to switch the polarization direction and the read current can detect whether the polarization is up or down. In such embodiments, a read operation is a destructive process, where the cell will lose the data contained therein, requiring a refresh to write data back to the cell.

Devices as disclosed herein generally have smaller unit areas than devices that are currently utilized. FIG. 5c illustrates the relevant dimension W. Assuming a cell as disclosed herein is a square; the space necessary for each cell is the width of the channel (W) plus the space necessary between cells (Space). However, because the effective width of the channel of a device as disclosed herein is 4 W (as seen in FIG. 5c), the width of the channel can be decreased by a factor of 4 and still provide the same properties. Therefore, assuming the channel is desired to have a width of 10 F and a space of F is necessary, a memory device as disclosed herein has a unit cell area of (3.5 F)(3.5 F), or 12.25 F²; and a device as discussed previously has a unit cell area of (2.5 F)(10 F+F), or 27.5 F². A memory cell as disclosed herein then has a unit cell area that is less than half as large as currently utilized memory cells.

Devices as disclosed herein also offer the advantage of having increased channel widths while not requiring excess space to increase the channel width. An increased channel width can increase the driving current that can be generated by the transistor, which can offer advantages to the memory device by affording effective switching currents to STRAM and RRAM memory cells.

Devices as disclosed herein an also offer longer channel lengths without requiring increased space. Longer channel lengths can avoid or minimize the short channel effect. The short channel effect refers to the difficulty in controlling “on” and “off” of a transistor due to leakage of current across the channel. Longer channel lengths minimize leakage of current and thereby decrease the short channel effect. The channel length in devices as disclosed herein is dictated, at least in part, by the thickness of the material making up the wordline.

Also disclosed herein is a method of making a memory device. Generally, any commonly utilized methods can be used to make memory devices as described herein. Semiconductor fabrication methods, including photolithography techniques can generally be utilized, for example.

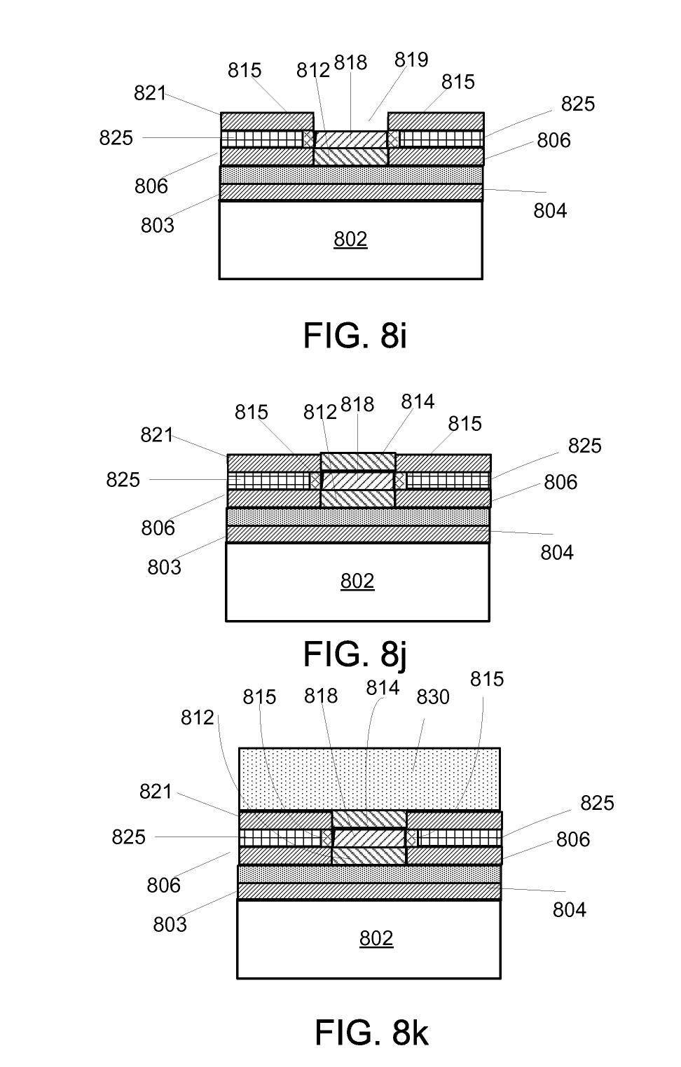

FIGS. 8a to 8k depict fabrication of a memory device as disclosed herein using an exemplary set of steps. The steps depicted in FIGS. 8a to 8k in no way limit the way in which a memory device as disclosed herein can be fabricated. It should also be noted that the figures are not necessarily to scale and do not necessarily depict the article at every state of preparation, i.e. intermediate stages of the article may not be illustrated in the sequence of figures. The materials and processes discussed with respect to FIGS. 8a to 8k also in no way limit materials or processes that can be utilized herein.

FIG. 8a depicts a substrate 802. The substrate 802 can include any substrate commonly utilized to fabricate memory devices. Exemplary substrates include, but are not limited to silicon, a mixture of silicon and germanium, and other similar materials. An exemplary first step includes deposition of a material to isolate the substrate 802 from other portions of the device. An exemplary insulator that can be utilized is silicon dioxide (SiO₂). The article in FIG. 8a depicts a first isolation layer 803 formed on the substrate 802. The isolation layer 803 can be deposited using known deposition methods, such as for example physical vapor deposition (PVD), chemical vapor deposition (CVD), electrochemical deposition (ECD), molecular beam epitaxy (MBE) and atomic layer deposition (ALD). The next step includes depositing a conductive material on the surface of the isolation layer 803 to form the first conductive layer 804. The first conductive layer 804 can function as the source line in a memory device that is part of an array, which functions to connect at least one other memory device to the one currently being fabricated. An exemplary conductive material that can be utilized is polycrystalline silicon (poly-Si). Other exemplary materials that can be utilized for this layer include, but are not limited to, CoSi and NiSi for example. The next step is to deposit a material on the first conductive layer 804 in order to isolate the first conductive layer 804, forming a second isolation layer 805. The second isolation layer 805 can, but need not be made from and deposited the same as the first isolation layer 803.

The article after the next step, patterning of the second isolation layer 805 is depicted in FIG. 8b. The second isolation layer 805 is patterned to form a patterned second isolation layer 806 and a first void region 807 that will ultimately be the source region. The second isolation layer 805 can be patterned (i.e. the patterned second isolation layer 806 and the first void region 807 can be formed) using generally known methods. Patterning generally describes a process or a series of processes that shape or alter the existing shape of the deposited materials and can be referred to as lithography. For example, in conventional lithography, the layer to be patterned can be coated with a chemical called photoresist. The photoresist can then be exposed by a stepper, a machine that focuses, aligns, and moves a mask, exposing select portions of the layer to light. The unexposed regions can be washed away by a developer solution. After etching or other processing, the remaining photoresist can be removed using various techniques, such as plasma etching.

FIG. 8c depicts the article after further steps have been carried out. Once the first void region 807 was formed (as depicted in FIG. 8b), a semi conductive material was deposited on the entire surface of the article (not shown in FIG. 8b). The semi conductive material could include silicon for example and could be deposited using known techniques, such as epitaxial growth or epitaxy. Epitaxy refers to a method of depositing a monocrystalline film on a substrate. This step functions to deposit a semi conductive material, such as silicon for example, in the first void region 807. The entire surface of the article can then be processed in order to remove any residual semi conductive material that may be present. One method of processing includes chemical-mechanical planarization (CMP). Next the semi conductive material, such as silicon within the first void region 807 is doped in order to alter the electrical properties of the silicon. Generally, doping can be carried out by ion implantation processes. The silicon can either be n-doped or p-doped. Once the silicon in the first void region 807 is doped, it is referred to as the source region 812, as shown in FIG. 8c.

FIG. 8d depicts the article after the next step, deposition of a conductive material on the surface of the article. The conductive material deposited at this step can function as the word line in a memory device that is part of an array, which functions to connect at least one other memory device to the one currently being fabricated. For this reason, this layer is referred to herein as the word line 825. A portion of the conductive material deposited in this step will also ultimately form the channel region. An exemplary conductive material that can be utilized is polycrystalline silicon (poly-Si). The conductive material, such as poly-Si can be deposited via epitaxy for example.

FIG. 8e depicts the article after the next step, deposition of a dielectric material layer 808 on the surface of the article. A portion of the dielectric material deposited at this step can function to insulate the gate of the transistor from the remainder of the device. The dielectric material can be an oxide, such as silicon dioxide. The dielectric material layer 808 can be deposited using methods such as those discussed above. FIG. 8f depicts the article after the next step, removal of a portion of the dielectric material layer 808, leaving a surface of the word line 825 and the gate oxide portions 815. Removal of the dielectric material layer 808 can be accomplished using known techniques, such as dry etching, wet etching or CMP. Removal of this portion of the dielectric material layer 808 leaves a second void region 816. The second void region 816 will ultimately be the channel region.

FIG. 8g depicts the article after the next step, deposition of a second semi conductive layer 817. The portion of the second semi conductive layer 817 disposed within the second void region 816 will ultimately function to form the channel region of the device. The second semi conductive layer 817 can generally include silicon, silicon geranium (SiGe), or other similar materials. The second semi conductive layer 817 can be deposited using methods such as those discussed above, including but not limited to, epitaxial growth. The material of the second semi conductive layer, at least the material within the second void region 816 once deposited is then doped. Generally, the material of the channel region is doped in an opposite fashion as that of the source region and the drain region. For example, if the source region and drain region are to be n-type doped, the channel region will be p-type doped; or vice versa. As discussed above, doping can generally be carried out using known techniques such as ion implantation techniques.

FIG. 8h depicts the channel region 818 formed from the steps carried out with respect to FIG. 8g. After the channel region 818 is doped, the surface of the article can then be processed in order to remove any residual semi conductive material that may be present. One method of processing includes CMP. After the residual semi conductive material has been removed, another layer of material, such as silicon dioxide (SiO₂) can be deposited, to form a third isolation layer 821. The third isolation layer 821 can be deposited as discussed above with respect to the first isolation layer and the second isolation layer.

FIG. 8i depicts the article after the next step, patterning of the third isolation layer 821 to form a patterned third isolation layer 822 and a third void region 819. The third void region 819 will ultimately be the drain region. The third void region 819 can be formed using patterning techniques as discussed above. The next step is to deposit a conductive material on the article, at least within the third void region 819 that will ultimately form the drain region. Once the conductive material is deposited, it is then doped to form the drain region 814, as depicted in FIG. 8j. The conductive material can be doped as discussed above. The drain region 814 is generally doped in the same manner as the source region 812 is, i.e. they are both n-type doped or are both p-type doped. After the drain region 814 is doped, the surface of the article can then be processed in order to remove any residual conductive material that may be present. One method of processing includes CMP.

Once the drain region has been doped, the transistor portion of the memory device has been formed. The next step is to form the memory cell upon the drain region 818. The article, after completion of this step, is depicted in FIG. 8k. As seen there, the memory cell 830 is formed at least on the surface of the drain region 814. Although the memory cell 830 in FIG. 8k extends beyond the periphery of the drain region 814, the memory cell can have the same footprint as the drain region 814, a smaller footprint than the drain region 814, or a larger footprint than the drain region 814. Particular steps involved with fabricating a memory cell 830 can vary depending on the particular type of memory cell that is being fabricated.

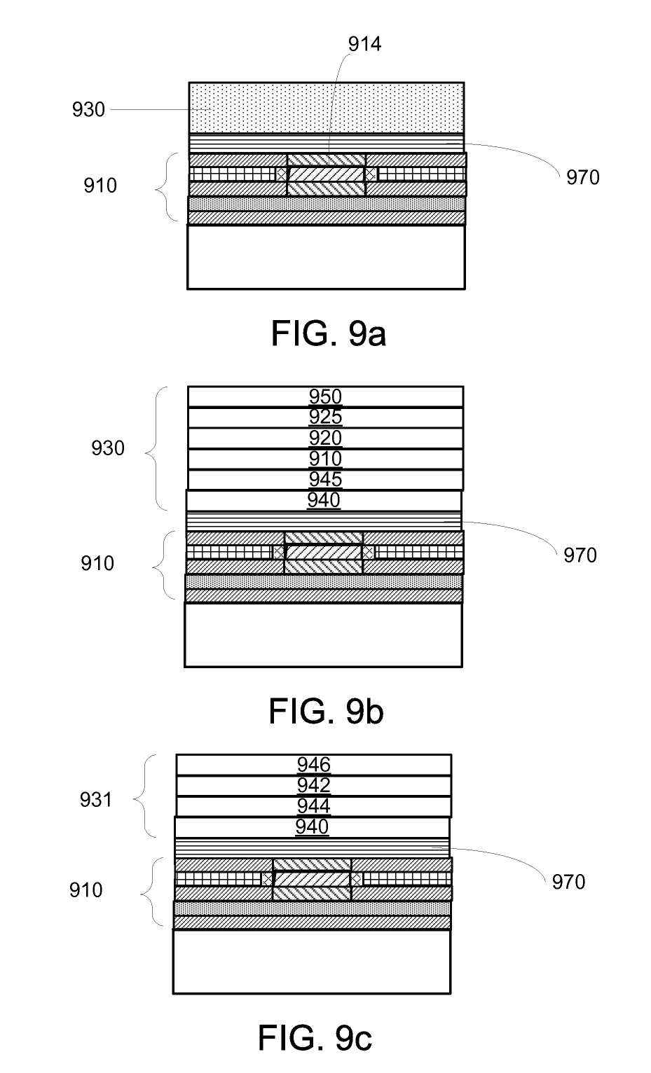

In an embodiment, depicted in FIG. 9a, an electrical contact layer 970 can be formed directly on the drain region 914. The electrical contact layer 970 generally functions to electrically connect the memory cell 930 with the transistor 910. In an embodiment, the electrical contact layer 970 can include a silicided layer, such as a nickel silicide (NiSi) layer or a titanium silicide (TiSi) layer for example. Generally utilized methods of depositing silicided layers can be utilized herein.

FIG. 9b illustrates an embodiment of a device disclosed herein that utilizes a STRAM memory cell. The device in FIG. 9b depicts the transistor 910, an electrical contact layer 970 and a memory cell 930. The memory cell 930 in FIG. 9b specifically exemplifies a bottom electrode layer 940, an antiferromagnetic layer 945, a first ferromagnetic layer (pinned layer) 910, an insulating layer 920, a second ferromagnetic layer (free layer) 925, and a second electrode layer 950. The bottom electrode layer 940 and the top electrode layer 950 can be made of materials that are commonly utilized for electrode layers within memory cells, including, but not limited to tungsten (W) and titanium nitride (TiN). The remaining layers can be made of materials such as those discussed above.

FIG. 9c illustrates an embodiment of a device disclosed herein that utilizes a RRAM memory cell. The device in FIG. 9c depicts the transistor 910, an electrical contact layer 970 and a memory cell 931. The memory cell 931 in FIG. 9c specifically exemplifies a bottom electrode layer 940, a first electrode 944, a medium layer 942, and a second electrode 946. The bottom electrode layer 940 can be made of materials that are commonly utilized for electrode layers within memory cells, including, but not limited to tungsten (W) and titanium nitride (TiN). The remaining layers can be made of materials such as those discussed above.

Thus, embodiments of VERTICALLY INTEGRATED MEMORY STRUCTURES are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation, and the present disclosure is limited only by the claims that follow.

What is claimed is:

1 A device comprising:
a transistor comprising:
a source region;
a drain region;
a channel region, wherein the channel region electrically connects the source region and the drain region along a channel axis; and
a memory cell, wherein the memory cell is disposed adjacent the drain region so that the channel axis runs through the memory cell.

2. The device according to claim 1, wherein the memory cell comprises a spin torque random access memory (STRAM) cell.

3. The device according to claim 1, wherein the bottom electrode layer of the STRAM cell is disposed adjacent the drain region of the transistor.

4. The device according to claim 1, wherein the memory cell comprises a resistive random access memory (RRAM) cell.

5. The device according to claim 1, wherein the RRAM cell is chosen from the group consisting of: polymer switching memory, phase change memory and Chalcogenide based conductive bridge memory.

6. The device according to claim 5, wherein the bottom electrode layer of the RRAM cell is disposed adjacent the drain region of the transistor.

7. The device according to claim 1 further comprising an electrical contact layer disposed between the drain region and the memory cell and directly on the drain region, wherein the electrical contact layer electrically connects the transistor with the memory cell.

8. The device according to claim 1, wherein the device has a unit cell area of less than about 20 F².

9. The device according to claim 1, wherein the transistor is a metal-oxide-semiconductor field effect transistor (MOSFET).

10. A memory array comprising:
a plurality of memory devices, each memory device comprising:
a transistor comprising:
a source region;
a drain region;
a channel region, wherein the channel region electrically connects the source region and the drain region along a channel axis;
an electrical contact layer disposed on the drain region;
a memory cell, wherein the memory cell is disposed adjacent the electrical contact layer so that the channel axis of the transistor runs through the memory cell and wherein the electrical contact layer electrically connects the transistor and the memory cell; and
a word line comprising the channel region of each transistor.

11. The array according to claim 10, wherein the memory cell comprises a spin torque random access memory (STRAM) cell.

12. The array according to claim 10, wherein the memory cell comprises a resistive random access memory (RRAM) cell.

13. The array according to claim 10, wherein the RRAM cell is chosen from the group consisting of: polymer switching memory, phase change memory and Chalcogenide based conductive bridge memory.

14. The array according to claim 10, wherein an electrode layer of the memory cell is disposed adjacent the electrical contact layer.

15. The array according to claim 14, wherein an antiferromagnetic layer of a STRAM cell is disposed on the electrode layer.

16. The array according to claim 14, wherein each of the plurality of devices has a unit cell area of less than about 20 F².

17. The array according to claim 14, wherein the transistor is a metal-oxide-semiconductor field effect transistor (MOSFET).

18. A method of forming a device comprising:
forming a source region;
forming a channel disposed on the source region;
forming a drain region disposed on the channel; and
forming a memory cell disposed on the drain region.

19. The method according to claim 18, further comprising forming an electrical contact layer on the drain region before the memory cell is formed and forming the memory cell on the electrical contact layer.

20. The method according to claim 18, wherein the memory cell comprises STRAM or RRAM.
